(19) United States
(12) Patent Application Publication
(10) Pub. No.: US 2024/0345184 A1
(43) Pub. Date: Oct. 17, 2024

(54) Metal Detector

(71) Applicant: Minelab Electronics Pty. Limited, Mawson Lakes (AU)

(72) Inventors: Sergii Shapoval, Mawson Lakes (AU); Alexander Albert John Makarowsky, Mawson Lakes (AU); Laurentiu Stamatescu, Mawson Lakes (AU); Philip Shane Wahrlich, Mawson Lakes (AU); Ruifeng Huang, Mawson Lakes (AU); Zili Xu, Mawson Lakes (AU)

(21) Appl. No.: 18/577,426

(22) PCT Filed: Jul. 8, 2022
(86) PCT No.: PCT/AU2022/050716

§ 371 Date: Jan. 8, 2024

(30) Foreign Application Priority Data
Jul. 9, 2021 (AU) 2021902109

(51) Int. Cl. G01R 33/028; B65F 1/16

(52) U.S. Cl. CPC G01R 33/028; B65F 1/16; B65F 2210/1525

(57) ABSTRACT

A metal detector in a cover of a container, including a first winding; an inner winding with a surface area that is less than that of the first winding; and an outer winding with a surface area that is greater than that of the first winding. The inner winding is connected in series with the outer winding such that a magnetic coupling between (a) the first winding and (b) the inner and outer windings connected in series is substantially zero. Shapes, locations and numbers of turns of the inner winding and the outer winding are selected such that the metal detector is less sensitive to a metal object outside the outer winding than inside the outer winding.

### CROSS REFERENCE TO RELATED APPLICATIONS

This application is the United States national phase of International Patent Application No. PCT/AU2022/050716 filed Jul. 8, 2022, and claims priority to Australian Provisional Patent Application No. 2021902109 filed Jul. 9, 2021, the disclosures of which are hereby incorporated by reference in their entireties.

### BACKGROUND OF THE INVENTION

### Field of the Invention

The present disclosure relates to a magnetic field antenna of a metal detector, in particular, to a metal detector in a cover of a container.

### Description of Related Art

In the hospitality and catering industry, such as restaurants, hotels, food courts, canteens etc., the loss of metal utensils or equipment may be very frequent, thus increasing the burden on the operators to replace the missing metal utensils or equipment. One of the main reasons for the loss of the utensils or equipment is due to human error disposing wanted and reusable metal utensils or equipment into disposal bins. For example, when a cleaner clears food scraps from a plate into a disposal bin, a fork may be disposed into the disposal bin at the same time. Metal utensils or equipment are expensive to replace, thus metal detectors are set up near or on disposal bins to produce an alert signal when wanted and reusable metal utensils or equipment are disposed into the disposal bin.

A disposal bin with a cover and a metal detector attached thereto to prevent a person from inadvertently disposing metal utensils or equipment is known. For such a disposal bin, a person may first deposit food scraps on the cover. When the metal detector detects wanted and reusable metal utensils or equipment, an alarm is produced so the person may check the food scraps for any wanted and reusable metal utensil or equipment. When there is no wanted and reusable metal utensil or equipment detected, the cover may be operable manually or automatically to allow the food scraps to be disposed in the disposal bin.

### SUMMARY OF THE INVENTION

According to a first aspect of the present disclosure, there is provided a metal detector in a cover of a container, comprising: a first winding; an inner winding with a surface area that is less than that of the first winding; and an outer winding with a surface area that is greater than that of the first winding; wherein the inner winding is connected in series with the outer winding such that a magnetic coupling between (a) the first winding and (b) the inner and outer windings connected in series is substantially zero; wherein shapes, locations and numbers of turns of the inner winding and the outer winding are selected such that the metal detector is less sensitive to a metal object outside the outer winding than inside the outer winding.

In one form, a sensitivity to a metal sphere of 1 mm radius at 12 cm radially away from the outer winding is at least 40 dB lower than a sensitivity inside the outer winding. In one form, shapes, locations and number of turns of the inner winding and the outer winding are selected such that the metal detector is more sensitive in a direction perpendicular to a plane of the outer winding. In one form, the first winding, the inner winding and the outer winding are substantially in a same plane. In one form, the first winding is connected to transmit electronics for transmitting a transmit magnetic field; the inner winding and the outer winding are connected in series to receive electronics for receiving a receive magnetic field. In one form, the first winding is connected to receive electronics for receiving a receive magnetic field; the inner winding and the outer winding are connected in series to transmit electronics for transmitting a transmit magnetic field. In one form, the first winding, the inner winding and the outer receive winding are concentric. In one form, the first winding is driven with a transmit signal with one or more spectral components; and signals induced in the inner winding and the outer winding in a presence of a target are processed to demodulate and low-pass filter each of the two or more spectral components into in-phase signals and quadrature signals, the demodulated and low-pass filtered in-phase signals and quadrature signals are further linearly combined to increase a detection of desired targets and to reduce a detection of undesired targets. In one form, a conical shape detection zone is formed on top of the cover. In one form, the metal detector is a multi-frequency metal detector with an attenuation at around 3 kHz and a peak sensitivity at around 30 kHz.

According to another aspect of the present disclosure, there is provided a cover for a container, comprising: an embedded metal detector, the metal detector comprising: a first winding; an inner winding with a surface area that is less than that of the first winding; and an outer winding with a surface area that is greater than that of the first winding; wherein the inner winding is connected in series with the outer winding such that a magnetic coupling between (a) the first winding and (b) the inner and outer windings connected in series is substantially zero; and wherein shapes, locations and numbers of turns of the inner winding and the outer winding are selected such that the metal detector is less sensitive outside the outer winding than inside the outer winding.

### BRIEF DESCRIPTION OF THE DRAWINGS

Embodiments of the present disclosure will be discussed with reference to the accompanying drawings wherein:

FIG. 1 depicts a general form of one embodiment of the present disclosure;

FIG. 2 depicts one embodiment of the present disclosure;

FIG. 3 depicts exemplary windings of a metal detector which is less sensitive outside the outer winding than inside the outer winding;

FIG. 4 depicts a measured influence zone of the metal detector of FIG. 3;

FIGS. 5a to 5c depict sensitivity measurement results of the metal detector of FIG. 3 at different distances away from the surface of a cover of a container;

FIG. 6 depicts an exemplary detection channel suitable for the metal detector of FIG. 3; and

FIG. 7 depicts more attenuation over the range of frequencies where the undesirable objects are located.

### DESCRIPTION OF THE INVENTION

It was discovered that a disposal bin is often located in an environment where there are many surrounding metallic objects. Thus, there is a challenge for the disposal bin with a cover and a metal detector to operate at a sufficiently high sensitivity in such an environment. The present disclosure presents an alternative cover for a bin with metal detection capability to reduce the impact of surrounding metal objects while maintaining high sensitivity to metallic objects on the disposal bin cover. Disposal bins are also known as trash cans, waste bins, disposals containers, rubbish bins etc.

In this disclosure, the term “winding” refers to a wound inductance consisting of multiple conductive wire turns. For example, a Double-D coil, also known as a DD coil, comprises two partially over-lapping windings, each comprises turns of conductive wires. The cross-sectional winding profile of most metal detector windings is usually compactly bundled, for example, the cross-sectional shape may be approximately square, or circular, or rectangular.

In a general form of one embodiment of this disclosure, there is provided a metal detector in a cover of a container. This metal detector may be embedded within the cover. Alternatively, the metal detector may be attachable and/or detachable from the cover. In such a form, the metal detector may be positioned on top, at the bottom, or within the cover.

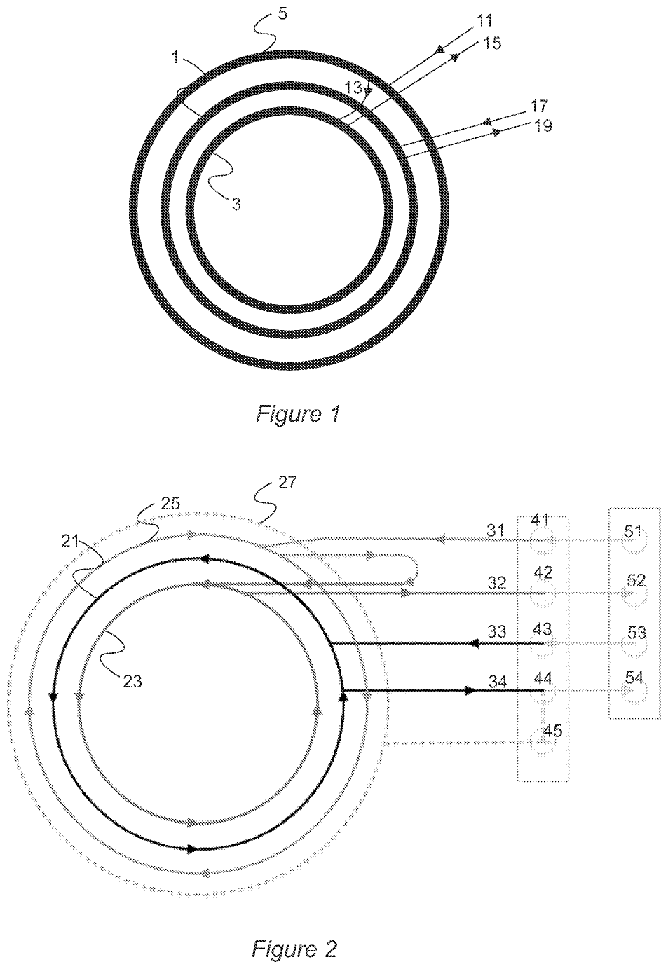

The metal detector in this embodiment comprises at least three windings. Referring to FIG. 1, the at least three windings are: a first winding 1, an inner winding 3 with a surface area less than the surface area of the first winding 1, and an outer winding 5 with a surface area greater than the surface area of the first winding 1. The first winding 1, the inner winding 3 and the outer winding 5 may be co-planar or may be in different planes. While in the embodiment shown in FIG. 1, they take the same shape of circles with different sizes, they may be of different shapes. For example, they may be rectangular shapes with rounded corners. They may share a same central point, just like the embodiment in FIG. 1 where they are concentric. They may also be configured in a way that they are not sharing a same central point.

The three windings are configured in the following manner: the inner winding 3 is connected in series with the outer winding 5 such that a magnetic coupling between (a) the first winding 1 and (b) the inner and outer windings 3, 5 connected in series is substantially zero. In other words, the first winding 1 and the inner and outer windings 3, 5 connected in series are nulled or induction balanced to each other. The term “substantially” means that the magnetic coupling does not need to be perfectly zero (i.e. does not need to be perfectly nulled), as long as a transmission by either (a) the first winding 1 and (b) the inner and outer windings 3, 5 connected in series, would not affect the functionality of the other acting as a receiver for the purpose of metal detection. For example, when they are not substantially nulled, the transmission may overload the receiver and wanted metal detection signals may be missed.

With reference to FIG. 1, if one injects a signal at 11, the signal travels through the outer winding 5 to the inner winding 3 connected in series through connection 13. The signal then travels through the inner winding 3 and exits at 15. Of course the signal direction may be reversed. For the first winding 1, signals are transmitted or received through 17, 19.

The inner and outer windings 3, 5 have three sets of main parameters, namely their shapes, their relative locations or positions, and the number of turns. These three sets of parameters are configured such that the metal detector is less sensitive outside the outer winding 5 than inside the outer winding 5.

FIG. 2 depicts an embodiment of the present disclosure. In this embodiment, the inner and outer windings 23, 25 connected in series are used as the receiver of the metal detector while the first winding 21 is used as the transmitter of the metal detector. In another form, the connection may be swapped in that the inner and outer windings 23, 25 connected in series are used as the transmitter of the metal detector while the first winding 21 is used as the receiver of the metal detector. However, the former arrangement is preferable, as some of the external EMI is cancelled by the subtraction of voltages induced by distant EMI sources in the inner and outer windings 23, 25.

A current flowing through the inner and outer windings 23, 25, and a current flowing through the first winding 21 are shown in FIG. 2. Terminals 51, 52 are terminals of receive electronics (not shown) while terminals 53, 54 are terminals of transmit electronics (not shown). Terminals 41, 42, 43, 44 and 45 are terminals near the casing 27 of the windings 21, 23, 25. For the receiver (inner winding 23 and outer winding 25 in this embodiment), a current flows from terminal 51 to terminal 41 in direction 31. The current first flows clockwise through outer winding 25 then anti-clockwise through inner winding 23 which is connected in series with the outer winding 25, and back to the receive electronics in direction 32 through terminal 42 and terminal 52. For the transmitter (first winding 21 in this embodiment), a current flows from terminal 53 to terminal 43 in direction 33. The current flows through the first winding 21 then back to the transmit electronics in direction 34 through terminal 44 and terminal 54. The casing 27 may incorporate an electrostatic shield which has a connection connected to terminal 44 (or alternatively connected to terminal 45, which is connected to terminal 44). The shield is connected to the electronics ground or another suitable low potential point. Alternatively, the electrostatic shield may be separately grounded.

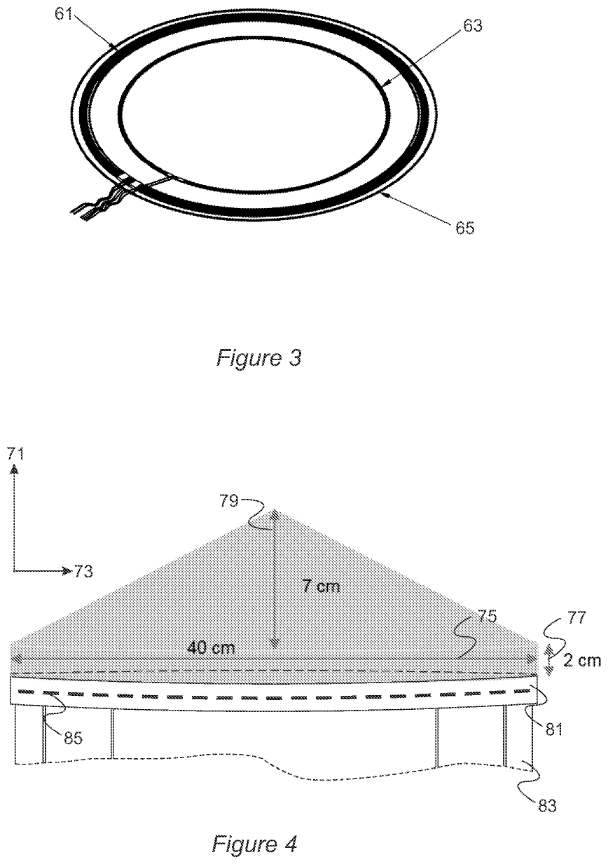

FIG. 3 depicts exemplary windings of a metal detector which is less sensitive to a metal target outside the outer winding than inside the outer winding. In this example, the first winding 61, the inner winding 63 and the outer winding 65 are concentric. Each of them of circular shape. The first winding 61 has an inner diameter of 319 mm and comprises 30 turns. Its inductance is approximately 780 H. The inner winding 63 has an inner diameter of 257 mm and comprises 16 turns. Its inductance is approximately 210H. The outer winding 65 has an inner diameter of 353 mm and comprises 8 turns. Its inductance is approximately 85 H. The combined inductance of the inner and outer windings is approximately 233 H. With these configurations, it was found that the metal detector functions as intended as explained below.

FIG. 4 depicts an intended influence zone of the metal detector of FIG. 3. The view in FIG. 4 is a side view of the plane of the windings. The vertical direction 71 of FIG. 4 is the face up direction of the cover and the horizontal direction 73 is parallel with the windings. In other words, a disposal bin 83 is located below the bottom most of FIG. 4. In this example, the cover 81 is a round cover with a diameter of approximately 40 cm on top of the disposal bin 83. The metal detector of FIG. 3 is embedded within the round cover 81 as indicated by trace 85, at approximately 1 cm below the top surface of the cover 81. The intended influence zone is the volume where a presence of a metal object within the volume may be detected by the metal detector. For the metal detector in FIG. 3, the influence zone of interest is primarily on top of the cover 81.

Through experimentation in kitchens, it was found that the influence zone should resemble a conical shape on top of a disk, with the height of the cone 79 being approximately 7 cm, the height of the disk measurement 77 of 2 cm and the cone base and disk diameter measurement 75 of 40 cm are close to the measurement of the round cover 81. The reason for this shape of the influence zone is that when the workers clean dishes on top of the cover 81, the food scraps accumulate in a pile and the objects of interest must be detected inside and on the surface of the pile.

To keep the specification succinct, the following technical discussion will be presented based on the case where the inner and outer windings connected in series are used as the receiver of the metal detector while the first winding is used as the transmitter of the metal detector. The same idea may be applied to the case where the inner and outer windings connected in series are used as the transmitter of the metal detector while the first winding is used as the receiver. The swapping of the transmitter and the receiver of the metal detector would not change the sensitivity to targets.

As explained previously, a disposal bin is often located in an environment where there are many surrounding metal objects. In one form, rejection of metallic objects outside the volume of interest may be done through winding design and the detection channels design with, for example, a multi-frequency metal detector.

The construction of the metal detector requires a relatively flat coil, sitting on the disposal bin. The bin may move with respect to the kitchen, for several possible reasons: it is placed on a non-flat surface, it is being handled roughly (and being tall with a small base it would wobble), it is on a trolley. Therefore, it may rock or move with respect to the environment. The objects that should be rejected outside the volume of interest include vertical metallic walls, fridges, dishwashers, ovens and similar appliances. Kitchen sinks, troughs, trolleys, racks may also cause problems. Many of them have stainless steel cladding and the material favoured in the kitchens is a non-magnetic variety. Other objects of smaller size that need to be rejected include operator worn watches, belt buckles, mobile phones etc.

The objects to be detected inside the volume of interest include all types of cutlery and tags for ceramic ramekins. Of course, while the discussion is in relation to a kitchen, it may be used in other locations and occasions.

The first part of the research is the selection of a particular coil topology, amongst multiple candidates. The first part of the research is the selection of suitable parameters (radii, number of turns) given the constraints.

Various coil topologies were investigated and it was found that a concentric coil is suitable as it is a flat coil, with good sensitivity within the coil, and with good rejection outside the coil. The normalisation with respect to a sphere at 3 cm from windings means that any coil will be able to detect the target 2 cm above the edge of the cover (the most difficult target position within the “desired detection volume” (cylinder+cone)). Assuming that the desired targets are detected there, then a design is better if it rejects more outside that volume. The object to be rejected may be very large physically (e.g. the face of a fridge) and therefore generate a substantial response compared to a target of interest (e.g. a ramekin tag). Hence, a correspondingly large attenuation of the order of 40 to 60 dB just outside the bin is highly desirable.

A concentric coil was further optimised according to the stated objectives. The cancellation of EMI may also be considered, if required.

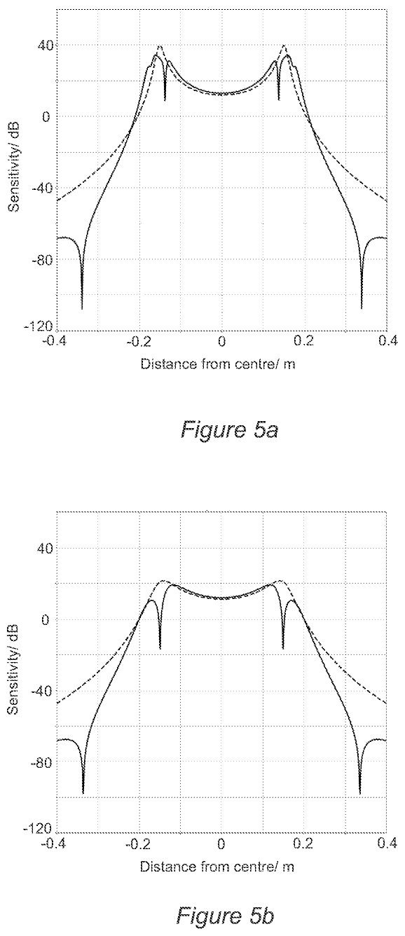

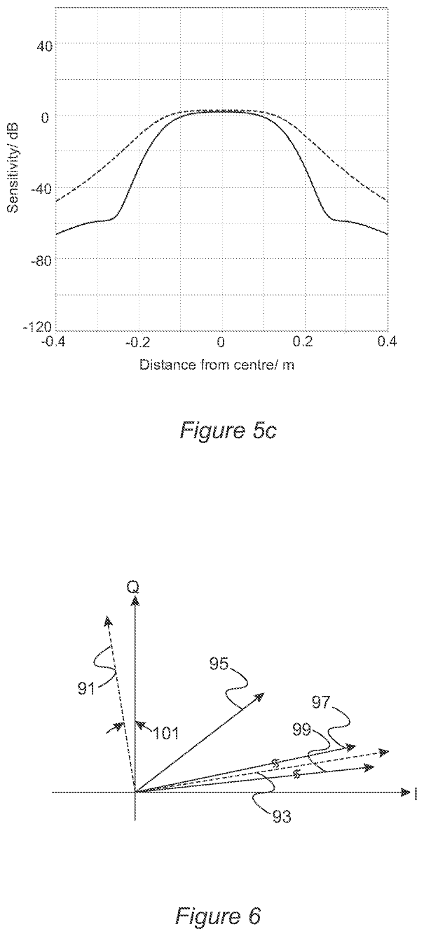

FIGS. 5a to 5c depict sensitivity measurement results of the metal detector of FIG. 3. The sensitivity of a concentric coil is compared to that of a mono-loop coil that also meets the sensitivity requirements inside the zone. In all cases, small test targets with isotropic responses (e.g. small conductive spheres) are scanned across the surface at 1 cm from the windings (FIG. 5a), at 3 cm from the windings (FIG. 5b) and at 10 cm from the windings (FIG. 5c). We assume that 0 dB corresponds to the detection threshold and both coils (mono-loop and concentric) are gain normalised to meet this condition for the test target at 3 cm from the coil at the edge of the detection zone, i.e. 20 cm from the centre (FIG. 5b). It can be seen that both coils detect targets in the centre up to 10 cm from the windings (FIG. 5c) and on the surface of the cover, i.e. at 1 cm from the windings (FIG. 5a). Outside the zone of influence though, the concentric coil is substantially less sensitive than the mono-loop coil, by at least 20 dB at 32 cm from the centre (the edge of the disposal bin).

An observation common during simulations is that the response to small targets inside the volume of interest has sharp nulls in certain locations and, for rings, it is orientation dependent. While having sensitivity nulls is undesirable, it is difficult to completely avoid them without considerably complicating the design of the detector, e.g. multiple coils concurrently operating on different frequencies. However, these nulls are very narrow, and small deviations from verticality mean that the disk becomes detectable. Also, as the targets have a certain physical extent and they are not point targets, means that the probability of being completely undetectable is very low.

Although the design of the coil provides very good spatial discriminative characteristics (objects outside versus objects inside), it is not sufficient to overcome the problem posed by the spurious detection of outside objects when the sensitivity is set sufficiently high to detect the desirable objects inside. An additional method to deal with this is to construct a detection channel that has good sensitivity to the targets of interest and low sensitivity to the typical and large undesirable objects (i.e. capable of generating large signals).

It was also discovered that most undesirable objects share the characteristic that they behave like low frequency non-ferrous targets as they are large objects made out of non-magnetic stainless steel. However, stainless steel has poor conductivity, so their frequency is not as low as if they were made out of aluminium, for example. Hence, the characteristics of these objects needed to be determined experimentally. Measurements of a variety of large undesirable kitchen objects (dishwashers, grills, deep fryers, ovens, sinks, trolleys etc.) showed that the characteristic frequencies of these objects tend to be grouped in the low kHz range (e.g. 2-5 kHz). On the other hand, measurements for the desirable objects showed that they have characteristic frequencies in the tens of kHz region. Based on these measurements, the detection channels were optimised to increase the signal to noise of the detection channels. In this context, signal refers to the desirable objects, while noise refers to undesirable objects.

A detection channel for the type of metal detector described in this application is designed differently to handheld detectors that operate in the ground and industrial detectors that find metal in foodstuff:
Handheld detectors aimed at finding gold nuggets, coin and treasure, landmines etc. are designed to reject magnetic and conducting grounds (soils). This is done by engineering the detection channel to detect metallic targets and reject signals specific to grounds (quite different both in time domain and frequency domain to those of metallic targets). There is a fine adjustment called ground balance which minimises the response of a particular ground.
Industrial metal detectors are aimed at finding small pieces of metal in foodstuff (the product). Their sensitivity is limited by the detection of the product and there is a process of balancing the metal detector to the product, such that the product response is minimised.

In one form, for a simple version, a metal detector in a cover may be obtained with a single frequency metal detector, by using a channel that is relatively insensitive to low frequency targets, i.e. a combination of in-phase and quadrature channels that reject low-frequency objects. However, better results are achieved if a multi-frequency design detector is being used, as the increased number of channels (pairs of in-phase and quadrature channels for each frequency).

The single frequency detector is sufficiently simple to illustrate the principle, as a linear combination of its channels can be interpreted as a rotation of the axis of the complex plane represented by the in-phase and quadrature channels. Assume that the target which requires highest sensitivity (e.g. the ceramic ramekin tag) to have a characteristic frequency of 30 kHz. Then a detector operating at approximately 30 kHz with the detection channel orthogonal to a target in the middle of the range of undesirable targets (e.g. 3 kHz) will offer a good signal to noise ratio. This is shown in FIG. 6, where the axis were rotated by an angle theta and the detection channel is calculated as the linear combination: D=−(in-phase)×sin(θ)+(quadrature)×cos(θ). In particular, it can be seen that the I axis (in-phase axis) and the Q axis (quadrature axis) are rotated by an angle 101 to become rotated axis 93 and rotated axis 91 respectively. Arrow 95 represents a response from a ramekin tag while arrows 97 and 99 represent responses from a dishwasher and an oven respectively. By rotating the axes, the response from the dishwasher and the oven projected on to the rotated Q axis is reduced, while the response from the ramekin tag projected on to the Q axis is still within a reasonably high level. Accordingly, by monitoring the Q channel, the ramekin tag may be easily detected, and not the dishwasher and the oven.

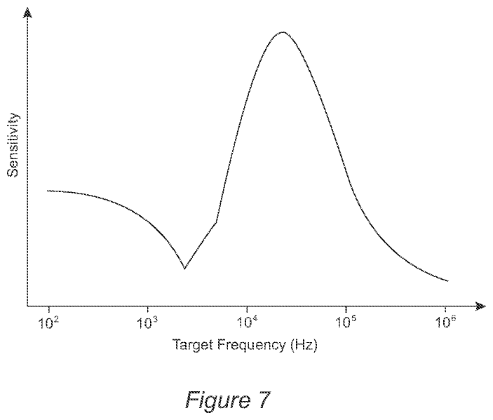

A multi-frequency detector, having more available information about the targets, is capable of producing more attenuation over the range of frequencies where the undesirable objects are located. An exemplary relative sensitivity graph is illustrated in FIG. 7. As can be seen, an attenuation is presented around the frequency of 3 kHz, while at the frequency of 30 kHz, the relative sensitivity is much higher than at the frequency of 3 kHz.

Those of skill in the art would understand that information and signals may be represented using any of a variety of technologies and techniques. For example, data, instructions, commands, information, signals, bits, symbols, and chips referenced throughout the above description may be represented by voltages, currents, electromagnetic waves, magnetic fields or particles, optical fields or particles, or any combination thereof.

Those of skill in the art would further appreciate that the various illustrative logical blocks, modules, circuits, and algorithm steps described in connection with the embodiments disclosed herein may be implemented as electronic hardware, computer software or instructions, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The steps of a method or algorithm described in connection with the embodiments disclosed herein may be embodied directly in hardware, in a software module executed by a processor, or in a combination of the two. For a hardware implementation, processing may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described herein, or a combination thereof. Software modules, also known as computer programs, computer codes, or instructions, may contain a number of source code or object code segments or instructions, and may reside in any computer-readable medium such as a RAM memory, flash memory, ROM memory, EPROM memory, registers, hard disk, a removable disk, a CD-ROM, a DVD-ROM, a Blu-ray disc, or any other form of computer-readable medium. In some aspects the computer-readable media may comprise non-transitory computer-readable media (e.g., tangible media). In addition, for other aspects computer-readable media may comprise transitory computer-readable media (e.g., a signal). Combinations of the above should also be included within the scope of computer-readable media. In another aspect, the computer-readable medium may be integral to the processor. The processor and the computer-readable medium may reside in an ASIC or related device. The software codes may be stored in a memory unit and the processor may be configured to execute them. The memory unit may be implemented within the processor or external to the processor, in which case it can be communicatively coupled to the processor via various means as is known in the art.

Further, it should be appreciated that modules and/or other appropriate means for performing the methods and techniques described herein can be downloaded and/or otherwise obtained by a computing device. For example, such a device can be coupled to a server to facilitate the transfer of means for performing the methods described herein. Alternatively, various methods described herein can be provided via storage means (e.g., RAM, ROM, a physical storage medium such as a compact disc (CD) or floppy disk, etc.), such that a computing device can obtain the various methods upon coupling or providing the storage means to the device. Moreover, any other suitable technique for providing the methods and techniques described herein to a device can be utilized.

In one form the invention may comprise a computer program product for performing the method or operations presented herein. For example, such a computer program product may comprise a computer (or processor) readable medium having instructions stored (and/or encoded) thereon, the instructions being executable by one or more processors to perform the operations described herein. For certain aspects, the computer program product may include packaging material.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It will be understood that the terms “comprise” and “include” and any of their derivatives (eg comprises, comprising, includes, including) as used in this specification is to be taken to be inclusive of features to which the term refers, and is not meant to exclude the presence of any additional features unless otherwise stated or implied

The reference to any prior art in this specification is not, and should not be taken as, an acknowledgement of any form of suggestion that such prior art forms part of the common general knowledge.

It will be appreciated by those skilled in the art that the disclosure is not restricted in its use to the particular application or applications described. Neither is the present disclosure restricted in its preferred embodiment with regard to the particular elements and/or features described or depicted herein. It will be appreciated that the disclosure is not limited to the embodiment or embodiments disclosed, but is capable of numerous rearrangements, modifications and substitutions without departing from the scope as set forth and defined by the following claims.

1. A metal detector in a cover of a container, comprising:
a first winding;
an inner winding with a surface area that is less than that of the first winding; and
an outer winding with a surface area that is greater than that of the first winding;
wherein the inner winding is connected in series with the outer winding such that a magnetic coupling between (a) the first winding and (b) the inner and outer windings connected in series is substantially zero; and
wherein shapes, locations and numbers of turns of the inner winding and the outer winding are selected such that the metal detector is less sensitive to a metal object outside the outer winding than inside the outer winding.

2. The metal detector of claim 1, wherein a sensitivity to a metal sphere of 1 mm radius at 12 cm radially away from the outer winding is at least 40 dB lower than a sensitivity inside the outer winding.

3. The metal detector of claim 1, wherein shapes, locations and numbers of turns of the inner winding and the outer winding are selected such that the metal detector is more sensitive in a direction perpendicular to a plane of the outer winding.

4. The metal detector of claim 1, wherein the first winding, the inner winding and the outer winding are substantially in a same plane.

5. The metal detector of claim 1, wherein the first winding is connected to transmit electronics for transmitting a transmit magnetic field; the inner winding and the outer winding are connected in series to receive electronics for receiving a receive magnetic field.

6. The metal detector of claim 1, wherein the first winding is connected to receive electronics for receiving a receive magnetic field; the inner winding and the outer winding are connected in series to transmit electronics for transmitting a transmit magnetic field.

7. The metal detector of claim 1, wherein the first winding, the inner winding and the outer receive winding are concentric.

8. The metal detector of claim 5, wherein the first winding is driven with a transmit signal with one or more spectral components; and signals induced in the inner winding and the outer winding in a presence of a target are processed to demodulate and low-pass filter each of the two or more spectral components into in-phase signals and quadrature signals, the demodulated and low-pass filtered in-phase signals and quadrature signals are further linearly combined to increase a detection of desired targets and to reduce a detection of undesired targets.

9. The metal detector of claim 1, wherein a conical shape detection zone is formed on top of the cover.

10. The metal detector of claim 1, wherein the metal detector is a multi-frequency metal detector with an attenuation at around 3 kHz and a peak sensitivity at around 30 kHz.

11. A cover for a container, comprising:
an embedded metal detector, the metal detector comprising:
a first winding;
an inner winding with a surface area that is less than that of the first winding; and
an outer winding with a surface area that is greater than that of the first winding;
wherein the inner winding is connected in series with the outer winding such that a magnetic coupling between (a) the first winding and (b) the inner and outer windings connected in series is substantially zero; and wherein shapes, locations and number of turns of the inner winding and the outer winding are selected such that the metal detector is less sensitive outside the outer winding than inside the outer winding.
